(19) United States
(12) Patent Application Publication
(10) Pub. No.: US 2023/0298159 A1
(43) Pub. Date: Sep. 21, 2023

(54) INTEGRATED CIRCUIT LAYOUT EXTRACTION USING PARALLELIZED TILE IMAGE PROCESSING

(71) Applicant: Battelle Memorial Institute, Columbus, OH (US)

(72) Inventors: Adam R. Waite, Centerville, OH (US); Adam G. Kimura, Westerville, OH (US); James E. Schaffranek, Westerville, OH (US)

(21) Appl. No.: 18/121,069

(22) Filed: Mar. 14, 2023

Related U.S. Application Data
(60) Provisional application No. 63/321,276, filed on Mar. 18, 2022.

(51) Int. Cl. G06T 7/00; H04N 23/695; G06T 1/20

(52) U.S. Cl. CPC G06T 7/001; H04N 23/695; G06T 1/20; G06T 2207/30148; G06T 2207/20092; G06T 2207/20212; G06T 2200/24; G06T 2207/10056

(57) ABSTRACT

An integrated circuit (IC) layout extraction method includes executing: an image receiving pipeline that, for each tile n of N tiles of an IC, receives a tile image n of the tile n of the IC acquired using a microscope; a layout portion extraction pipeline that extracts a layout portion n from each received tile image n; and a layout portion comparison pipeline that compares each layout portion n with a corresponding portion of the reference IC layout. The image receiving pipeline, the layout portion extraction pipeline, and the layout portion comparison pipeline are parallel pipelines that are executed by the electronic processor concurrently in time. The extracted layout portions for the N tiles of the IC are combined to form the extracted layout for the IC.

This application claims the benefit of provisional application No. 63/321,276 filed Mar. 18, 2022, which is incorporated herein by reference in its entirety. This invention was made with government support under contract number FA8650-15-D-1953 awarded by Air Force Research Laboratory (AFRL). The government has certain rights in the invention.

### BACKGROUND

The following relates to the semiconductor integrated circuit (IC) decomposition arts, IC layout extraction arts, IC verification and validation arts, and the like.

Circuit layout extraction from a physical IC finds numerous applications, such as verification and quality control of IC deliverables received from an outsource semiconductor foundry, IC security validation to ensure circuitry is free of unauthorized or malicious functionality, extraction of a functional description of an obsolete or otherwise unavailable IC to enable manufacture of functionally equivalent ICs, and so forth. Many such tasks rely on a reference IC layout to which the physical IC is expected to conform. The reference IC layout is typically in an industry-standard format such as Graphic Design System II (GDSII) or Open Artwork System Interchange Standard (OASIS). To compare the physical IC with the reference IC layout, the IC is removed from its package (if it was originally in packaged form), delayered, and each layer imaged using optical microscopy or scanning electron microscopy (SEM). Image features corresponding to metal traces, vias, and/or circuit components in the layer images are then compared with corresponding layers of the reference IC layout.

### BRIEF SUMMARY

In accordance with some illustrative embodiments disclosed herein, an integrated circuit (IC) layout extraction system comprises: a microscope; an electronic processor; a display operatively connected with the electronic processor; and a non-transitory storage medium that stores instructions readable and executable by the electronic processor to perform an IC layout extraction method. The IC layout extraction method includes performing an iterative method N times to extract N layout portions of an IC wherein the performing of each iteration of the iterative method includes: (i) receiving a tile image of a tile of the IC acquired by the microscope; and (ii) extracting a layout portion from the tile image. The IC layout extraction method further includes combining the extracted N layout portions to form an extracted layout for the IC.

In accordance with some illustrative embodiments disclosed herein, a non-transitory storage medium stores a reference IC layout, and instructions readable and executable by an electronic processor to perform an IC layout extraction method including executing: an image receiving pipeline that, for each tile n of N tiles of an IC, receives a tile image n of the tile n of the IC acquired using a microscope; a layout portion extraction pipeline that extracts a layout portion n from each received tile image n; and a layout portion comparison pipeline that compares each layout portion n with a corresponding portion of the reference IC layout. The image receiving pipeline, the layout portion extraction pipeline, and the layout portion comparison pipeline are parallel pipelines that are executed by the electronic processor concurrently in time.

In accordance with some illustrative embodiments disclosed herein, an integrated circuit (IC) layout extraction method comprises: (i) moving a field of view (FOV) of the microscope to a tile of the IC and acquiring a tile image of the next tile using the microscope; (ii) extracting a layout portion from the tile image; (iii) repeating the operations (i) and (ii) for all tiles of the IC; and (iv) combining the extracted layout portions to form an extracted layout for the IC. The operations (i), (ii), (iii), and (iv) are suitably performed using a computer.

### BRIEF DESCRIPTION OF THE DRAWINGS

Any quantitative dimensions shown in the drawing are to be understood as non-limiting illustrative examples. Unless otherwise indicated, the drawings are not to scale; if any aspect of the drawings is indicated as being to scale, the illustrated scale is to be understood as non-limiting illustrative example.

FIG. 1 diagrammatically shows an illustrative system for extracting the layout of an integrated circuit (IC).

FIG. 2 diagrammatically shows an illustrative process for extracting the layout of an IC chip.

FIG. 3 diagrammatically shows an illustrative multiple pipeline process for extracting the layout of an IC chip using the system of FIG. 1.

FIG. 4 diagrammatically shows the illustrative process of FIG. 3 by way of a flowchart.

### DETAILED DESCRIPTION

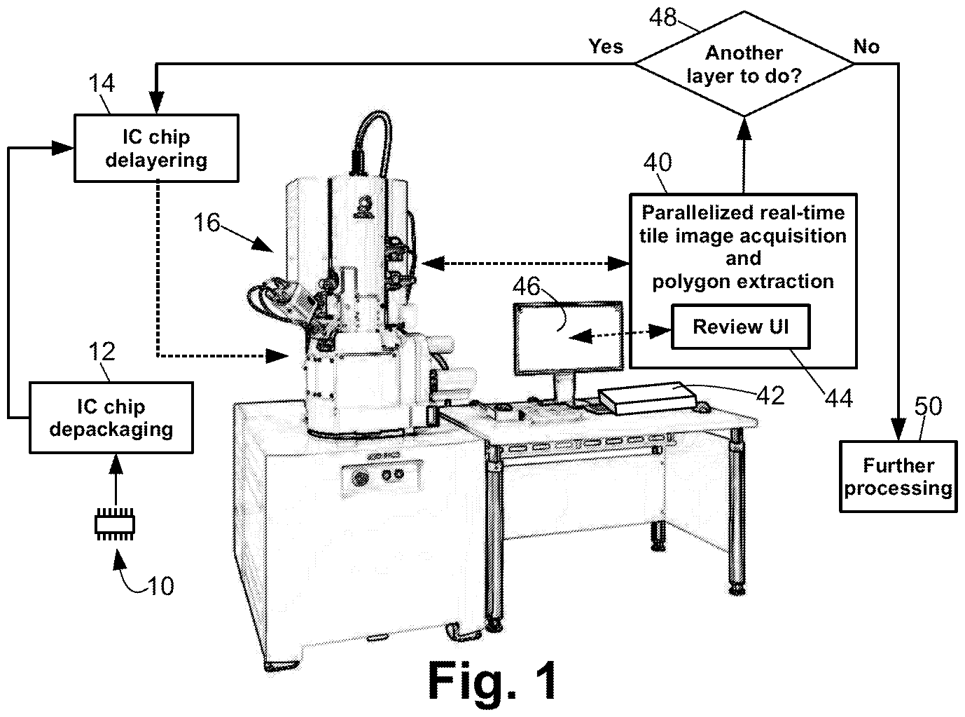

With reference to FIG. 1, an illustrative system for extracting the layout of an integrated circuit (IC) 10 is illustrated. The IC 10 may be delivered as a packaged IC chip (as shown in FIG. 1), or may be delivered as a diced, but not packaged chip, or may be delivered as a wafer of silicon (or another substrate) on which the IC 10 on which an array of ICs including the IC 10 are fabricated. The illustrative example shows the IC 10 in a dual in-line package, but other types of IC packaging could be used. The IC 10 is a physical IC. By the term “physical IC” an actually fabricated IC is meant, for example physically fabricated on a silicon wafer, or on a silicon-on-insulator (SOI) wafer, or another substrate, and including actually fabricated circuit components such as field-effect transistors (FETs), diodes, and so forth produced in FEOL processing, which are electrically interconnected by electrically conductive traces formed during BEOL processing, which are typically arranged as multiple patterned metal layers with vias running between layers and between layers and circuit components.

If the IC 10 is packaged, then in a manual or semi-automated or fully automated operation 12 it is depackaged to extract the IC chip from the package. In an operation 14, the IC is delayered to expose a layer of the IC 10 for imaging. The detailed delayering process depends on the layer being exposed and the details of the IC 10. For example, when processing the BEOL processing product, the delayering preferentially removes intermetal dielectric (IMD) to expose a patterned metal layer comprising conductive traces which are imaged. Thereafter, another delayering step may be performed by etching to remove the metal of the metal layer and subsequent imaging to produce a layer image of the vias underlying the just-removed metal layer, and so forth to provide layer images of the metal layers and the vias between the layer images, and finally the FETs or other semiconductor devices that were produced in the FEOL processing. Optionally, the FEOL processing product can be similarly delayered and layer images acquired, using etches that remove specific oxide, metal, or other layers or features of the FETs, diodes, or other circuit components.

Each delayering step exposes a surface of the IC 10 for imaging. The illustrative layout extraction system employs a scanning electron microscope 16 to acquire the images of the IC, for example using a backscattered electron detector and/or a secondary electron detector. However, other types of imaging devices may be employed, such as an optical microscope. A computer or electronic processor 18 controls the microscope 16 to acquire images. More specifically, to acquire sufficiently high resolution images to extract the IC layout, the microscope 16 is controlled to acquire as set of N tile images of a corresponding N tiles of the IC 10. As used herein, a tile is a region of the IC 10, and the set of tiles typically forms a two-dimensional grid of tiles that encompass the circuit area of the IC 10. Without loss of generality, the number of tiles is denoted herein by N, and the N tile images of the corresponding N tiles are acquired in an order tile 1, tile 2, tile 3, . . . , tile N. For notational convenience, an index n is used, i.e. tile 1 is n=1, tile 2 is n=2, tile 3 is n=3, . . . , and tile N is n=N. For practical reasons, the tiles are typically arranged in rows and columns forming a Cartesian grid, with successive tiles positioned next to each other, so that the tile image acquisition can be done row-by-row down the columns (or vice versa).

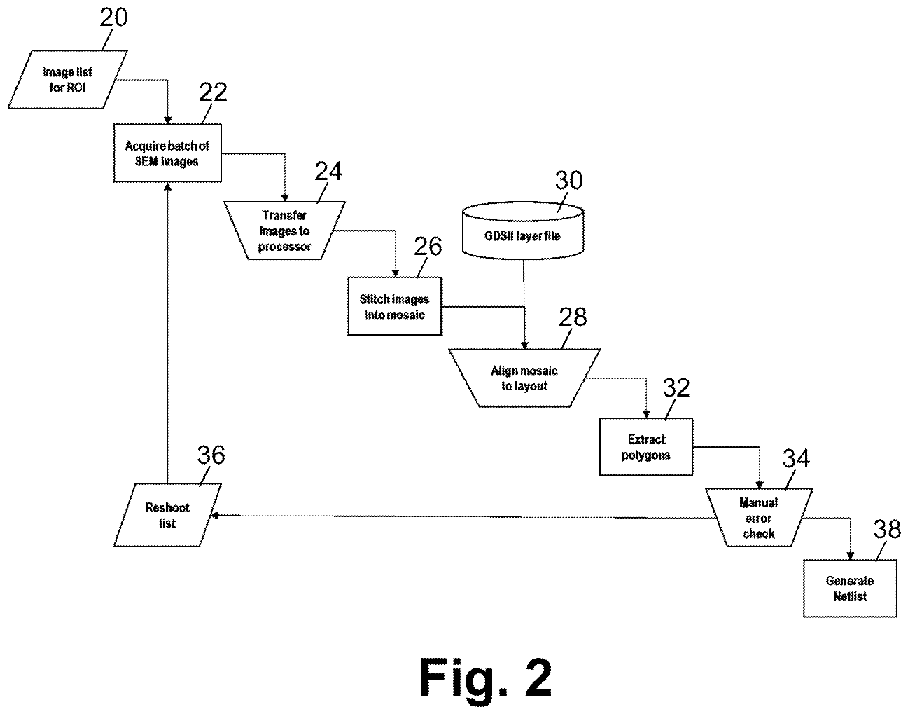

With brief reference to FIG. 2, in one approach a waterfall or serial processing sequence may be employed. An image list or queue 20 of the tiles of the IC 10 serves as input. In an operation 22 the batch of tile images corresponding to the tiles of the IC 10 are acquired. The images are stored in a memory of the SEM, and in an operation 24 the batch of tile images is transferred to a layout extraction processor. In an operation 26 the tile images are stitched together to form a mosaic image. To achieve the stitching, neighboring tiles typically overlap, e.g. for a Cartesian arrangement of rectangular tiles each centrally located tile overlaps neighboring tiles on four sides, each side-positioned tile overlaps neighboring tiles on three sides, and each corner-positioned tile overlaps neighboring tiles on two sides. In an operation 28, the resulting mosaic image is aligned to a reference IC layout 30, which in the illustrative example is a reference Graphic Design System II (GDSII) layout, although the reference IC layout 30 could be in another format such as an Open Artwork System Interchange Standard (OASIS) format. In an operation 32 the mosaic image is processed to extract the layout of the physical IC. Various approaches can be used, such as combinations of threshold, gaussian blur, and histogram equilibrium filters that may be utilized in conjunction with a trained neural network to convert the stitched raster images into vector-based polygons. In some embodiments, as the layout is expected to conform to a large degree to the reference IC layout 30, the latter can be used as a priori knowledge for the operation 32 in extracting the layout of the physical IC. The output of the operation 32 is the extracted layout of the IC. In an operation 34, a manual or semi-manual error check may be performed. For example, an automated comparison of the extracted layout and the reference IC layout 30 may be performed, and any areas that do not match may be presented to a user in the operation 34 by displaying the relevant portion of the mosaic image, the relevant portion of the extracted layout, and the relevant portion of the reference IC layout 30. Discrepancies could be due to actual differences between the reference IC layout 30 and the layout of the IC as reflected in the extracted layout; however, discrepancies could also be due to artifacts in that portion of the image and/or errors in the layout extraction process 32. If image artifact problems are identified, then the user may reject the image portion and in an operation 36 the corresponding tiles of the IC are re-imaged per operation 22 and the process repeated. The final extracted layout after acceptance by the user in operation 34 may then be used for downstream tasks such as converting the layout to a netlist 38.

The waterfall or serial IC layout extraction process of FIG. 2 has certain disadvantages as recognized herein. At any given time, most of the computing resources are sitting idle while waiting for the batch of tile images to be received via the operation 24. Furthermore, even with an experienced SEM operator and established workflow, several images in a batch may ultimately prove unsuitable for accurate polygon extraction in the operation 32 due to drift, sample charging, or the presence of artifacts from delayering. Such problematic images are detected only near the end of the process (i.e. at error check 34), and these problematic images can only at that point be addressed by re-acquiring the problematic image tiles (“reshoot” 36) and repeating the entire waterfall pipeline. Moreover, it can be tedious to reposition the field-of-view (FOV) of the microscope to the problematic tile or tiles for a reshoot.

With returning reference to FIG. 1, these difficulties with the process of FIG. 2 are addressed by employing a parallelized real-time image acquisition and polygon extraction process 40 implemented on a computer 42 that controls the microscope 16 and provides a reviewing user interface 44 presented on a display 46 operatively connected with the electronic processor 42. In this approach, each tile image is acquired and processed to extract a layout portion corresponding to the tile image, without reference to other tile images. This enables the extraction processing to be done concurrently with the acquisition of the tile images. Moreover, any problematic images can be identified early, during the layout portion extraction from that tile image, thus enabling re-imaging within a few tile images of the problematic tile image. This simplifies returning to the FOV of the problematic tile image and reshooting.

With continuing reference to FIG. 1, after completion of the imaging and layout extraction for a current layer of the IC 10, flow passes to a decision block 48 where it is determined whether any additional layers need to be imaged. If so, the flow returns to the operation 14 for further delayering to expose the next layer. If at the decision operation 48 it is determined that layouts for all layers have been extracted then flow passes to further processing 50, such as generation of a netlist for example.

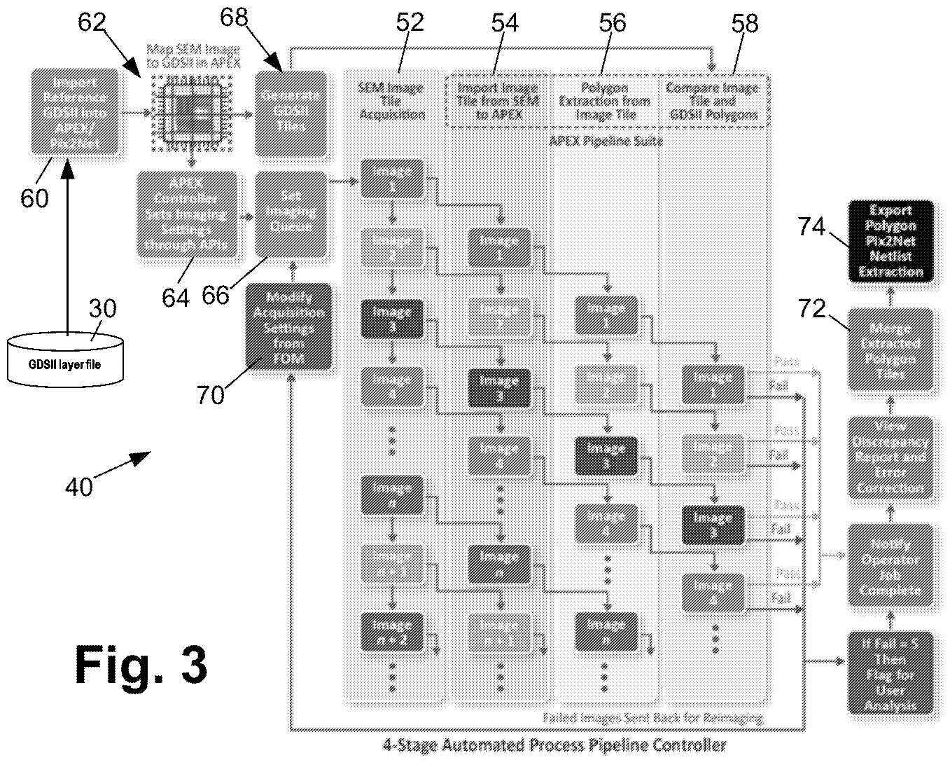

With reference to FIG. 3, an illustrative embodiment of the parallelized real-time tile image acquisition and polygon extraction process 40 is described. The approach uses a first-in, first-out (FIFO) workflow to the image tiles. As soon as an image tile is acquired by SEM 16, it is dispatched to polygon extraction and error check. More particularly, the illustrative parallelized real-time tile image acquisition and polygon extraction process 40 of FIG. 3 includes four parallel pipelines: an image acquisition pipeline 52; an image receiving pipeline 54; a layout portion extraction pipeline 56; and a layout portion comparison pipeline 58. Without loss of generality, the electronic processor or computer 42 (see FIG. 1) is referred to in FIG. 3 as “APEX”, and the APEX computer 42 implements the three processing pipelines 54, 56, 58. The image acquisition pipeline 52 may be automated by the computer 42, or may be semiautomated, e.g. with a human SEM operator participating in setup of the SEM 16 for the imaging.

An input to the illustrative parallelized real-time tile image acquisition and polygon extraction process 40 of FIG. 3 is the reference IC layout 30 which is imported 60 and serves as a map 62 of the IC 10 for segmenting the area of the IC into the N tiles. The map 62 is transformed 64 into microscope control settings to define the queue 66 of tiles, and the map 62 is also used to segment the reference IC layout 30 into reference layout portions 68 corresponding to the tiles. For each tile n of N tiles of the (depackaged and delayered) IC 10 in the queue 66, the image acquisition pipeline 52 controls the microscope 16 to move a field of view (FOV) of the microscope 16 to tile n of the IC and acquires a tile image n of the tile n using the microscope. In the illustrative image acquisition pipeline 52, each tile image is referred to as an “Image n”, e.g. “Image 1”, “Image 2”, . . . . The image receiving pipeline 54 receives each acquired tile image n shortly after its acquisition, and as seen in FIG. 3 approximately concurrently with the acquisition of the next tile image by the image acquisition pipeline 52.

The layout portion extraction pipeline 56 extracts a layout portion n from each received tile image n. Various approaches can be used, such as combinations of threshold, gaussian blur, and histogram equilibrium filters that may be utilized in conjunction with a trained neural network to convert the stitched raster images into vector-based polygons. As the layout extracted from the tile image is expected to conform to a large degree to the corresponding tile 68 of the reference IC layout 30, the latter can be used as a priori knowledge in extracting the layout portion from the tile image. In some embodiments, the layout portion extraction pipeline 56 extracts the layout portion n only from each corresponding tile image n and not from any other tile image received by the image receiving pipeline. This facilitates the parallel processing. The layout portion comparison pipeline 58 compares each layout portion n with a corresponding portion of the reference IC layout 30, namely with the corresponding tile 68 of the reference IC layout 30. Various comparison approaches can be used for this comparison, such as using a trained artificial neural network (ANN) or other artificial intelligence (AI) component trained on samples, or detecting differences between the layout portion n and the corresponding reference IC layout portion using homeomorphic error detection techniques such as topological equivalence analysis and/or topological coverage analysis. The comparison for a given layout portion n of the portion comparison pipeline 58 can be performed concurrently with the layout portion extraction of the layout portion extraction pipeline 56 for the previous tile image n−1, again facilitating the parallel processing.

More generally, the image receiving pipeline 54, the layout portion extraction pipeline 56, and the layout portion comparison pipeline 58 are thus parallel pipelines that are executed by the electronic processor 42 concurrently in time (along with the image acquisition pipeline 52 which is performed under automated or semi-automated control of the processor 42, and/or by manual operator control).

With continuing reference to FIG. 3, if the comparison of an extracted layout portion n with the corresponding portion of the reference IC layout 30 does not satisfy an acceptance criterion, then one or more remedial actions may be performed. The acceptance criterion may, for example, include the two conditions that:
(1) No more than E₁ IC elements (e.g., circuit component, or metallization trace, or via, or so forth) of the reference IC layout portion fail to be matched to a corresponding IC element of the extracted layout portion n, AND
(2) No more than E₂ IC elements of the extracted layout portion n fail to be matched to a corresponding IC element of the corresponding reference IC layout portion.
   The error counts E₁ and E₂ can be tuned to determine how many differences are acceptable. The errors can also be referred to as discrepancies. In this illustrative example, any comparison of an extracted layout portion n with the corresponding portion of the reference IC layout 30 that fails to meet both conditions (1) and (2) does not satisfy the acceptance criterion, leading to the remediation.

In one example, the remediation may include re-acquiring the tile image via pipeline 52, and repeating the operations of receiving the re-acquired tile image via pipeline 54, extracting the layout portion via pipeline 56, and repeating the comparison via pipeline 58. To implement this, in the example of FIG. 3 flow passes to a block 70 which inserts tile image back into the queue 66.

In another example, the computer 42 may include at least one user input device (e.g., a keyboard, mouse, trackball, various combinations thereof, et cetera, and the remediation may include displaying the extracted layout portion and the corresponding portion of the reference IC layout on the display 46 and receiving an indication via the at least one user input device of whether to accept the extracted layout portion.

As seen on the right side of FIG. 3, once all tile images have been acquired and transferred by pipelines 52 and 54 and layout portions extracted and compared per pipelines 56 and 58, flow passes to subsequent operations such as optionally merging or combining 72 the extracted N layout portions to form an extracted layout for the IC, and further optionally generating 74 a netlist from the extracted layout.

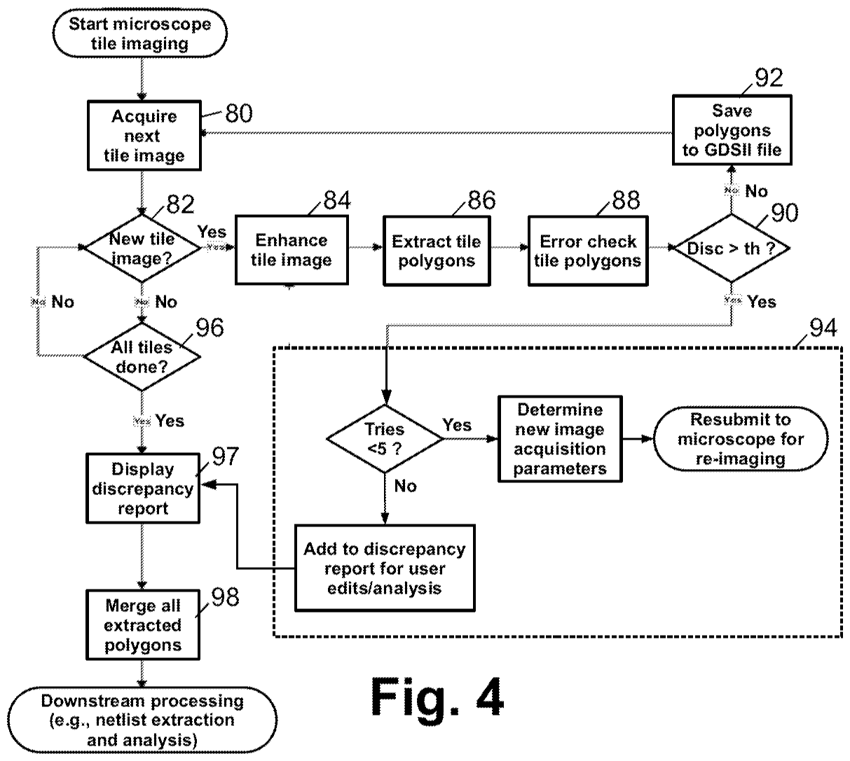

FIG. 4 diagrammatically shows the illustrative process of FIG. 3 by way of a flowchart. The acquisition 80 of the next tile image is performed by the pipeline 52. Operation 82 corresponds to the image receiving pipeline 54. The image enhancement 84 and polygon extraction 86 corresponds to the layout portion extraction pipeline 56, while the error check 88 corresponds to the layout portion comparison pipeline 58. If the comparison satisfies the acceptance criterion at decision 90 then the extracted layout portion is stored 92 in a suitable format such as a GDSII file. If the comparison does not satisfy the acceptance criterion at decision 90 then a suitable remediation 94 is performed. At a decision 96, when it is determined that all tile images have been acquired and processed, flow passes to post-processing in which a discrepancy report is displayed 97 and the extracted N layout portions are merged or combined 98 to form an extracted layout for the IC. In the discrepancy report 97, discrepancies may be for example IC elements of the reference IC layout portion that fail to be matched to a corresponding IC element of the extracted layout portion n, or IC elements of the extracted layout portion n that fail to be matched to a corresponding IC element of the corresponding reference IC layout portion.

The preferred embodiments have been illustrated and described. Obviously, modifications and alterations will occur to others upon reading and understanding the preceding detailed description. It is intended that the invention be construed as including all such modifications and alterations insofar as they come within the scope of the appended claims or the equivalents thereof.

1. An integrated circuit (IC) layout extraction system comprising:
a microscope;
an electronic processor;
a display operatively connected with the electronic processor; and
a non-transitory storage medium storing instructions readable and executable by the electronic processor to perform an IC layout extraction method including:
performing an iterative method N times to extract N layout portions of an IC wherein the performing of each iteration of the iterative method includes:
(i) receiving a tile image of a tile of the IC acquired by the microscope; and
(ii) extracting a layout portion from the tile image; and
combining the extracted N layout portions to form an extracted layout for the IC.

2. The IC layout extraction system of claim 1 wherein the non-transitory storage medium further stores a reference IC layout and each iteration further includes:
(iii) comparing the extracted layout portion with a corresponding portion of the reference IC layout; and
(iv) if the comparison does not satisfy an acceptance criterion then performing at least one remedial action.

3. The IC layout extraction system of claim 2 wherein the at least one remedial action includes repeating the operation (i) to receive a re-acquired tile image that is re-acquired by the microscope and repeating the operations (ii) and (iii) for the received re-acquired tile image.

4. The IC layout extraction system of claim 2 further comprising:
at least one user input device;
wherein the non-transitory storage medium further stores a reference IC layout and the at least one remedial action includes displaying the extracted layout portion and the corresponding portion of the reference IC layout on the display and receiving an indication via the at least one user input device of whether to accept the extracted layout portion.

5. The IC layout extraction system of claim 1 wherein each iteration of the iterative method performed after the first iteration overlaps the performing of at least one preceding iteration in time.

6. The IC layout extraction system of claim 1 wherein, for each iteration of the iterative method, the operation (ii) extracts the layout portion only from the tile image received by operation (i) of that same iteration.

7. The IC layout extraction system of claim 1 wherein the combining of the extracted N layout portions to form the extracted layout for the IC is performed after completion of all N iterations of the iterative method.

8. The IC layout extraction system of claim 1 wherein each tile of the IC overlaps at least two other tiles of the image.

9. The IC layout extraction system of claim 1 wherein the microscope comprises a scanning electron microscope (SEM) or an optical microscope.

10. A non-transitory storage medium storing:
a reference integrated circuit (IC) layout; and
instructions readable and executable by an electronic processor to perform an IC layout extraction method including executing:
an image receiving pipeline that, for each tile n of N tiles of an IC, receives a tile image n of the tile n of the IC acquired using a microscope;
a layout portion extraction pipeline that extracts a layout portion n from each received tile image n; and
a layout portion comparison pipeline that compares each layout portion n with a corresponding portion of the reference IC layout;
wherein the image receiving pipeline, the layout portion extraction pipeline, and the layout portion comparison pipeline are parallel pipelines that are executed by the electronic processor concurrently in time.

11. The non-transitory storage medium of claim 10 wherein:
the image receiving pipeline operates on a queue of tiles of the IC; and
the layout portion comparison pipeline re-inserts the tile n into the queue of tiles for re-imaging in response to the comparison failing an acceptance criterion.

12. The non-transitory storage medium of claim 10 wherein the layout portion extraction pipeline extracts the layout portion n only from each corresponding tile image n and not from any other tile image received by the image receiving pipeline.

13. The non-transitory storage medium of claim 10 wherein the IC layout extraction method further includes:
combining of the extracted layout portions for the N tiles of the IC to form the extracted layout for the IC;
wherein the combining is not part of the image receiving pipeline and is not part of the layout portion extraction pipeline and is not part of the layout portion comparison pipeline.

14. The non-transitory storage medium of claim 10 wherein the IC layout extraction method further includes executing:
an image acquisition pipeline that, for each tile n of N tiles of an IC, controls the microscope to move a field of view (FOV) of the microscope to tile n of the IC and acquires a tile image n of the tile n using the microscope, the acquired tile image being received via the image receiving pipeline.

15. An integrated circuit (IC) layout extraction method comprising:
(i) moving a field of view (FOV) of the microscope to a tile of the IC and acquiring a tile image of the next tile using the microscope;
(ii) extracting a layout portion from the tile image;
(iii) repeating the operations (i) and (ii) for all tiles of the IC; and
(iv) combining the extracted layout portions to form an extracted layout for the IC;
wherein the operations (i), (ii), (iii), and (iv) are performed using a computer.

16. The IC layout extraction method of claim 15 wherein the operation (ii) includes:
(a) comparing the extracted layout portion with a corresponding portion of a reference IC layout; and
(b) if the comparison does not satisfy an acceptance criterion then performing at least one remedial action.

17. The IC layout extraction method of claim 16 wherein the at least one remedial action includes repeating the operation (i) to re-acquire the tile image and repeating the operation (ii) for the re-acquired tile image.

18. The IC layout extraction method of claim 14 wherein each repetition of the operations (i) and (ii) overlaps at least one preceding occurrence of the operations (i) and (ii) in time.

19. The IC layout extraction method of claim 14 wherein each repetition of the operation (ii) extracts the layout portion only from the tile image acquired by the occurrence of operation (i) immediately preceding in time.

20. The IC layout extraction system of claim 14 wherein the operation (iv) is started only after completion of the operation (iii).
